(19) United States
(12) Patent Application Publication
(10) Pub. No.: US 2007/0178710 A1
(43) Pub. Date: Aug. 2, 2007

(54) Method for sealing thin film transistors

(75) Inventors: Dawn V. Muyres, Saint Paul, MN (US); Tommie W. Kelley, Coon Rapids, MN (US); Michael A. Haase, Saint Paul, MN (US); Paul F. Baude, Maplewood, MN (US); Steven D. Theiss, Woodbury, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 10/642,919

(22) Filed: Aug. 18, 2003

(51) Int. Cl. H01L 21/31; H01L 21/469

(52) U.S. Cl. 438/778

(57) ABSTRACT

A method for sealing thin film transistors comprises providing a thin film transistor comprising a gate electrode, a gate dielectric, a source and a drain electrode, and an semiconductor layer; and vapor depositing a sealing material on at least a portion of the semiconductor layer through a pattern of an aperture mask.

### FIELD

This invention relates to methods for making and sealing thin film transistors.

### BACKGROUND

The properties of a thin film transistor (TFT) can be degraded when its semiconductor layer is exposed to certain environments (for example, solvents during wet processing). Thus, suitable sealing materials have been sought to protect TFT semiconductors. In particular, there has been interest in protecting or sealing organic semiconductors. Organic thin film transistors (OTFTs) (that is, TFTs having an organic semiconductor) are gaining attention as a technology that enables a variety of applications centered around low-cost electronics. The view is that organic semiconductors can be synthesized to incorporate the necessary electronic properties for a wide variety of devices. These devices can also be constructed to allow low-cost, reel-to-reel processing that is not currently possible for crystalline silicon microelectronics. Organic semiconductor materials are generally intolerant to wet processing, however. Processing approaches for organic TFTs have therefore been limited.

Previous efforts to protect or seal semiconductor materials may result in decreased semiconductor performance, particularly for organic semiconductors. Conformal coatings, for example, have been applied to organic semiconductor devices to protect them from degradation, but the coatings have typically decreased device performance or caused failure. Many known methods also require more than one processing step. For example, some methods involve encapsulating an entire TFT with an encapsulant and then using photolithography, which involves applying a photoresist to the area to remain, etching away the area not protected by the photoresist, and optionally removing the photoresist. Other known methods involve applying a thin layer of photosensitized material (for example, photosensitized polyvinyl alcohol) to the semiconductor layer, exposing the photosensitized material to ultraviolet light, and then removing the unexposed photosensitized material.

### SUMMARY

In view of the foregoing, we recognize that there is a need for a quick, easy, and less damaging method of sealing TFT semiconductor layers to provide a barrier to the environment and allow for further processing, including wet processing, to be carried out on top of the device. Briefly, in one aspect, the present invention provides a method for sealing thin film transistors. The method comprises (a) providing a thin film transistor comprising a gate electrode, a gate dielectric, a source and a drain electrode, and a semiconductor layer; and (b) vapor depositing a sealing material on at least a portion of the semiconductor layer through a pattern of an aperture mask.

In another aspect, the invention provides a method of making a thin film transistor comprising the steps of (a) providing a substrate; (b) depositing a gate electrode material on the substrate through a pattern of an aperture mask; (c) depositing a gate dielectric on the gate electrode material through a pattern of an aperture mask; (d) depositing a semiconductor layer adjacent to the gate dielectric through a pattern of an aperture mask; (e) depositing a source electrode and a drain electrode contiguous to the semiconductor layer through a pattern of an aperture mask; and (f) vapor depositing a sealing material on at least a portion of the semiconductor layer through a pattern of an aperture mask. Preferably, the steps of this method of making a thin film transistor are performed in the order listed. Each of the steps (b) through (e) can be vapor deposited, and the deposition steps can be performed in the order recited.

In still another aspect, the invention provides a thin film transistor comprising a substrate, a gate electrode, a gate dielectric, a source and a drain electrode, a semiconductor layer, and a vapor deposited sealing layer on at least a portion of the semiconductor layer.

the sealing layer insulates the device from other electronic components, and isolates from environmental contaminants such as humidity and water. Advantageously, the sealing material can be deposited and patterned in a single step, by means of the recited aperture mask. Heretofore, a patterned sealing material could only be deposited through multiple steps. Further, it has been discovered that the above-described methods provide TFTs with increased solvent resistance and scratch resistance. Surprisingly, OTFTs made according to the methods of the invention exhibit relatively little decrease in performance.

In addition, the entire TFT, including the sealant layer, can be fabricated using aperture masking techniques. The methods of the invention may add only one additional processing step to the standard aperture masking procedure. Furthermore, the whole TFT can be fabricated in its entirety without ever breaking vacuum.

Thus, the methods of the invention meet the need in the art for a quick, easy, and less damaging method of sealing TFT semiconductor layers.

### DESCRIPTION OF DRAWING

FIG. 1 depicts a sealed thin film transistor of the invention.

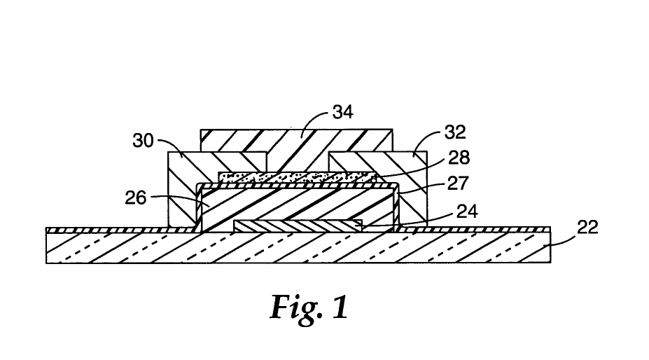

### DETAILED DESCRIPTION

Thin film transistors (TFTs), generally include a gate electrode, a gate dielectric on the gate electrode, a source electrode and a drain electrode adjacent to the gate dielectric, and a semiconductor layer adjacent to the gate dielectric and adjacent to the source and drain electrodes (see, for example, S. M. Sze, Physics of Semiconductor Devices, 2^{nd} edition, John Wiley and Sons, page 492, New York (1981)). These components can be assembled in a variety of configurations.

Gate Electrode

The gate electrode of a TFT can be any useful conductive material. For example, the gate electrode can comprise doped silicon, or a metal, such as aluminum, copper, chromium, gold, silver, nickel, palladium, platinum, tantalum, and titanium, and transparent conducting oxides such as indium tin oxide. Conductive polymers also can be used, for example polyaniline or poly(3,4-ethylenedioxythiophene) /poly(styrene sulfonate) (PEDOT:PSS). In addition, alloys, combinations, and multilayers of these materials can be useful. In some TFTs, the same material can provide the gate electrode function and also provide the support function of a substrate. For example, doped silicon can function as the gate electrode and support the TFT.

Gate Dielectric

The gate dielectric is generally provided on the gate electrode. The gate dielectric electrically insulates the gate electrode from the balance of the TFT device. It can be deposited on the TFT as a separate layer, or formed on the gate by oxidizing (including anodizing) the gate material to form the gate dielectric. The gate dielectric preferably has a relative dielectric constant above about 2 (more preferably, above about 5). The dielectric constant of the gate dielectric can be relatively high, for example, 80 to 100 or higher. Useful materials for the gate dielectric can comprise, for example, organic or inorganic electrically insulating materials.

Inorganic materials can be used as the sole dielectric in the device. Specific examples of organic materials useful for the gate dielectric include polymeric materials, such as polyvinylidenefluoride (PVDF), cyanocelluloses, polyimides, epoxies, and the like. Other useful organic materials are described in copending application U.S. Ser. No. 10/434,377, filed on May 8, 2003, which is herein incorporated by reference. An inorganic capping layer can comprise the outer layer of an otherwise polymeric gate dielectric.

Specific examples of inorganic materials useful for the gate dielectric include strontiates, tantalates, titanates, zirconates, aluminum oxides, silicon oxides, tantalum oxides, titanium oxides, silicon nitrides, barium titanate, barium strontium titanate, and barium zirconate titanate. In addition, alloys, combinations, and multilayers of these materials can be used for the gate dielectric.

Preferred inorganic materials for the gate dielectric include aluminum oxides, silicon oxides, and silicon nitrides.

Source and Drain Electrodes

The source electrode and drain electrode are separated from the gate electrode by the gate dielectric, while the semiconductor layer can be over or under the source electrode and drain electrode. The source and drain electrodes can be any useful conductive material. Useful materials include most of those materials described above for the gate electrode, for example, aluminum, barium, calcium, chromium, copper, gold, silver, nickel, palladium, platinum, titanium, transparent conducting oxides such as indium tin oxide, polyaniline, PEDOT:PSS, other conducting polymers, alloys thereof, combinations thereof, and multilayers thereof. Some of these materials are appropriate for use with n-type semiconductor materials and others are appropriate for use with p-type semiconductor materials, as is known in the art.

Semiconductors

The semiconductor layer can comprise organic or inorganic semiconductor materials. Useful inorganic semiconductor materials include amorphous silicon, tellurium, zinc oxide, zinc selenide, zinc sulfide, cadmium sulfide, and cadmium selenide (preferably, amorphous silicon). Useful organic semiconductor materials include acenes and substituted derivatives thereof. Particular examples of acenes include anthracene, naphthalene, tetracene, pentacene, and substituted pentacenes (preferably pentacene or substituted pentacenes, including fluorinated pentacenes). Other examples include semiconducting polymers, perylenes, fullerenes, phthalocyanines, oligothiophenes, polythiophenes, polyphenylvinylenes, polyacetylenes, metallophthalocyanines and substituted derivatives. Useful bis-(2-acenyl) acetylene semiconductor materials are described in copending application U.S. Ser. No. 10/620027, filed on Jul. 15, 2003, which is herein incorporated by reference.

Substituted derivatives of acenes include acenes substituted with at least one electron-donating group, halogen atom, or a combination thereof, or a benzo-annellated acene or polybenzo-annellated acene, which optionally is substituted with at least one electron-donating group, halogen atom, or a combination thereof. The electron-donating group is selected from an alkyl, alkoxy, or thioalkoxy group having from 1 to 24 carbon atoms. Preferred examples of alkyl groups are methyl, ethyl, n-propyl, isopropyl, n-butyl, sec-butyl, n-pentyl, n-hexyl, n-heptyl, 2-methylhexyl, 2-ethylhexyl, n-octyl, n-nonyl, n-decyl, n-dodecyl, n-octadecyl, and 3,5,5-trimethylhexyl. Substituted pentacenes and methods of making them are taught in copending applications U.S. Ser. No. 10/256489 and U.S. Ser. No. 10/256616, both filed on Sep. 27, 2002, which are herein incorporated by reference.

Further details of benzo-annellated and polybenzo-annellated acenes can be found in the art, for example, in NIST Special Publication 922 “Polycyclic Aromatic Hydrocarbon Structure Index”, U.S. Govt. Printing Office, by Sander and Wise (1997).

Sealant

TFTs made according to the present invention include a sealing layer. Useful materials for the sealing layers include those materials that can be vapor deposited and have a resistivity of at least 10× that of the semiconductor layer (preferably at least 100×). Generally the sealing layer has a resistivity of at least 1×10⁶ ohm-cm. The sealing layer is present on at least a portion of the semiconductor layer (preferably, the sealing material also covers at least a portion of the source and drain electrodes; more preferably, the sealing material covers the active portion of the TFT). The sealing layer can comprise either organic or inorganic materials, or both.

Specific examples of organic materials useful for the sealing layer include polymeric material that can be vapor deposited, such as, for example, polyvinylidenefluoride (PVDF), polystyrene, polyimides, epoxies, and the like. Specific examples of inorganic materials useful for the sealing layer include strontiates, tantalates, titanates, zirconates, aluminum oxides, silicon oxides, tantalum oxides, titanium oxides, silicon nitrides, barium titanate, barium strontium titanate, and barium zirconate titanate. In addition, alloys, combinations, and multilayers of these materials can be used for the sealing material.

Preferably, the sealing material is a metal oxide, metal nitride, silicon oxide, silicon nitride, or parylene. Parylene is a general term used to describe a class of poly-p-xylenes that are derived from a dimer having the following structure: 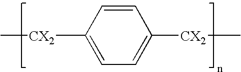
wherein X is H or halogen. Parylene coatings are generally applied from their respective dimers by a deposition process in which the dimer is vaporized, pyrolyzed (that is, cleaved into the monomer vapor form), and supplied to a deposition chamber. The deposition process is known in the art and is described, for example, in U.S. Pat. No. 5,536,319.

As used herein, “parylene” includes all of the parylene coatings such as, for example, 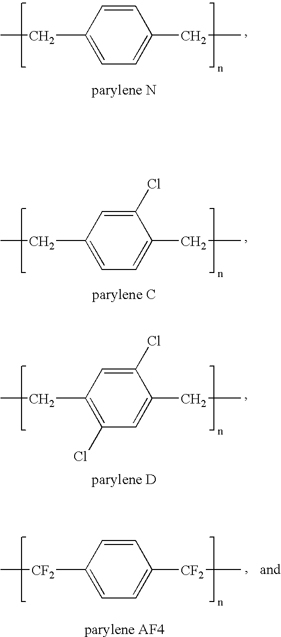
substituted parylenes.

For some embodiments, a transparent sealing material is preferred. For example, a sealing layer of metal oxides may provide desirable transparency to devices such as photoemitters and photodetectors.

TFTs made according to the present invention can include multiple layers of sealing materials to provide better barrier properties. For example, TFTs made according to the present invention can optionally include a metal layer on top of the sealing material. Generally, metals provide excellent barrier properties. The TFT will short, however if the metal is placed directly on the device. Therefore, it is necessary that the sealing layer be between the metal layer and the TFT. Suitable materials for the metal layer include, for example, aluminum, chromium, gold, silver, nickel, palladium, platinum, tantalum, zinc, tin, indium, and titanium.

It is also contemplated that additional active layers, possibly comprising added devices, may be stacked on top of sealing material. These stacked devices can also be encapsulated with sealing material on top of the stack. It is thus possible that multiple layers of devices separated by sealing materials can be made using the methods of this invention.

Substrate

TFTs made according to the present invention can be provided on a substrate. The substrate typically supports the TFT during manufacturing, testing, and/or use. For example, one substrate may be selected for testing or screening various embodiments while another substrate is selected for commercial embodiments. Optionally, the substrate can provide an electrical function for the TFT. Useful substrate materials include organic and inorganic materials. For example, the substrate can comprise inorganic glasses, ceramic foils, polymeric materials (for example, acrylics, epoxies, polyamides, polycarbonates, polyimides, polyketones, poly(oxy-1,4-phenyleneoxy-1,4-phenylenecarbonyl -1,4-phenylene) (sometimes referred to as poly(ether ether ketone) or PEEK), polynorbornenes, polyphenyleneoxides, poly(ethylene naphthalenedicarboxylate) (PEN), poly(ethylene terephthalate) (PET), poly(phenylene sulfide) (PPS)), filled polymeric materials (for example, fiber-reinforced plastics (FRP)), fibrous materials, such as paper and textiles, and coated or uncoated metallic foils.

A flexible substrate is used in some embodiments of the present invention. This allows for roll processing, which may be continuous, providing economy of scale and economy of manufacturing over flat and/or rigid substrates. The flexible substrate chosen preferably is capable of wrapping around the circumference of a cylinder of less than about 50 cm diameter (preferably, less than about 25 cm diameter; more preferably, less than about 10; most preferably, less than about 5 cm) without distorting or breaking. The force used to wrap the flexible substrate of the invention around a particular cylinder typically is low, such as by unassisted hand (that is, without the aid of levers, machines, hydraulics, and the like). The preferred flexible substrate can be rolled upon itself.

Fabrication

The thin film electrodes (that is, the gate electrode, source electrode, and drain electrode), can be provided by any useful means such as, for example, plating, ink jet printing, or vapor deposition (for example, thermal evaporation or sputtering). Preferably, the thin film electrodes are provided by vapor deposition. The semiconductor layer can be provided by any useful means such as, for example, solution deposition, spin coating, printing techniques, or vapor deposition (preferably, by vapor deposition). The sealing material can be provided by vapor deposition, and patterned using aperture masking.

The patterning of the thin film electrodes and the semiconductor layer can be accomplished by known methods such as aperture masking, additive photolithography, subtractive photolithography, printing, microcontact printing, and pattern coating (preferably, by aperture masking). The patterning of the sealing material can be accomplished using aperture masking.

In some embodiments of the current invention, the gate electrode, gate dielectric, semiconductor layer, source electrode and drain electrode, and sealing material are each vapor deposited through a pattern of one or more aperture masks. Multiple patterns can be used comprising one or more aperture masks for deposition of the component layers. Individual layers can be deposited through the same or different patterns on one or more aperture masks. Aperture masks enable deposition of a desired material and, simultaneously, formation of the material in a desired pattern. Accordingly, there is no need for a separate patterning step preceding or following deposition.

Preferably, the TFT layers or features are deposited through the pattern of an aperture mask formed from a polymer material such as, for example, polyimide or polyester. Polymer aperture masks typically have a thickness of between about 5 microns and about 50 microns. The use of pylymeric materials for the aperture masks can provide advantages over other materials, including ease of facrication of the aperture mask, reduced cost of the aperture mask, and other advantages. However, non-polymeric materials such as, for example, silicon, metals, or crystalline materials can be used. Polymer aperture masks are flexible and are generally less prone to damage due to the accidental formation of creases or permanent bends, though. In addition, polymer aperture masks are less damaging to existing deposited layers. furthermore, some polymer masks can be cleaned with acids.

Two or more TFT layers or features can be deposited through one or more aperture masks, or each of the TFT layers or features can be deposited through a single aperture mask. The arrangement and shape of deposition apertures are subject to wide variation depending upon the TFT and circuit layout envisioned by the user. One or more deposition apertures can be formed to have widths less than approximately 1000 microns (preferably, less than approximately 50 microns; even more preferably, less than approximately 20 microns; even more preferably, less than approximately 10 microns; most preferably, less than approximately 5 microns). By forming deposition apertures to have widths in these ranges, the sizes of the TFT or circuit elements may be reduced. Moreover, a distance (gap) between two deposition apertures can be less than approximately 1000 microns (preferably, less than approximately 50 microns; more preferably, less than approximately 20 microns; most preferably, less than approximately 10 microns) to reduce the size of various TFT or circuit elements. When making, using, reusing, or repositioning the aperture masks the distances between features, such as the distance between apertures or the distance between sub-patterns can be reproducible to within approximately 1.0 percent (preferably, approximately 0.5 percent, more preferably, approximately 0.1 percent).

Laser ablation techniques can be used to define the pattern of deposition apertures in polymer aperture masks. Accordingly, formation of an aperture mask from a polymeric film can allow the use of fabrication processes that can be less expensive, less complicated, and/or more precise than those generally required for other aperture masks such as, for example, silicon masks or metallic masks. Moreover, because laser ablation techniques can be used to create a pattern, the width of the pattern can be made much larger than conventional patterns. For example, laser ablation techniques can facilitate the creation of a pattern such that the width of the pattern is greater than approximately one centimeter, greater than approximately 25 centimeters, greater than approximately 100 centimeters, or even greater than approximately 500 centimeters. These large masks, which can be the width of a web, and very long (for example, the length of a roll), can then be used in a deposition process to create TFT or circuit elements that are distributed over a large surface area and separated by large distances.

Alternatively, if an aperture mask is formed from a silicon wafer, the pattern of apertures can be created using reactive ion etching or laser ablation.

Each of the TFT layers or features can also be deposited through one or more separate aperture masks of a mask set. A mask set includes a number of aperture masks for use in a deposition process. Mask sets can include any number of aperture masks, for example, depending upon the TFT or circuit element to be created in the deposition process. The masks form a “set” in that each mask can correspond to a particular layer or set of TFT or circuit elements within a TFT or integrated circuit. Each aperture mask can be formed with a pattern of deposition apertures that defines at least a part of a layer of a TFT or circuit.

Each aperture mask in a mask set preferably comprises a polymer. Laser ablation techniques can then be used to form one or more deposition apertures as described above.

A deposition station can be used for performing a vapor deposition process in which material is vaporized and deposited on a substrate through an aperture mask. The deposition station is typically a vacuum chamber. After an aperture mask is placed in proximity to a substrate, the material to be deposited is vaporized by a deposition unit. The deposition unit can include a boat of material that is heated to vaporize the material. The vaporized material deposits on the substrate through the aperture(s) of an aperture mask to define at least a portion of a TFT or circuit layer on the substrate. Upon deposition, the material forms the pattern defined by the aperture mask. When each layer of a TFT of the invention (that is, the gate electrode, the gate dielectric, the semiconductor, the source and drain electrodes, and the sealing material) is vapor deposited in a vacuum chamber, the TFT can be fabricated in its entirety without breaking vacuum.

When flexible aperture masks are made sufficiently large, for example, to include a pattern that has large dimensions, a sag problem can arise. In particular, when such a flexible aperture mask is placed in proximity to a deposition substrate, the flexible aperture mask can sag as a result of gravitational pull on the flexible aperture mask. This problem is usually most apparent when the aperture mask is positioned underneath the deposition substrate. Moreover, the sag problem can compound as the flexible aperture mask is made larger and larger.

A variety of techniques can be used to address the sag problem or otherwise control sag in aperture masks during a deposition process. For example, the flexible aperture mask can have a first side that can removably adhere to a surface of a deposition substrate to facilitate intimate contact between the aperture mask and the deposition substrate during the deposition process. In particular, the first side can include a pressure sensitive adhesive that can be removed after the deposition process.

Another way to control sag is to use magnetic force. For example, an aperture mask can comprise both a polymer and magnetic material. The magnetic material can be coated or laminated on the polymer, or can be impregnated into the polymer. For example, magnetic particles can be dispersed within a polymeric material used to form the aperture mask. When a magnetic force is used, a magnetic field can be applied within a deposition station to attract or repel the magnetic material in a manner that controls sag in the aperture mask.

Yet another way to control sag is the use of electrostatics. The aperture mask can comprise a polymer that is electrostatically coated or treated. A charge can be applied to the aperture mask, the deposition substrate, or both to promote electrostatic attraction in a manner that controls sag in the aperture mask.

Still another way to control sag is to stretch the aperture mask. A stretching unit can be implemented to stretch the aperture mask by an amount sufficient to reduce, eliminate, or otherwise control sag. As the mask is stretched tightly, sag can be reduced. In order to control sag using stretching, the aperture mask needs to have an acceptable coefficient of elasticity.

Additionally, the concept of stretching a polymeric aperture mask can also be used to properly align the aperture mask for a deposition process.

Another challenge to TFT and circuit fabrication using aperture mask deposition techniques relates to the difficulty in aligning the aperture masks with deposited layers on the deposition substrate. Moreover, as more and more layers of a TFT or circuit are deposited, the alignment problem can be compounded.

Aperture masks can therefore comprise a mask substrate having alignment edges. A pattern of deposition apertures can be defined in the mask substrate in relation to the alignment edges such that spatial alignment of the edges of the mask substrate aligns the pattern for the deposition process. If each mask in a mask set is formed with the same alignment edges, the masks can be easily aligned relative to deposited layers during sequential depositions.

The deposition substrate can include alignment edges that substantially correspond to the alignment edges of the aperture mask. In this manner, spatial alignment of the edges of the aperture mask and the edges of the deposition substrate properly aligns the pattern relative of the deposition apertures relative to the deposition substrate for the deposition process. Furthermore, as mentioned above, if each mask in a mask set has similar alignment edges, alignment of each mask relative to deposited layers can be easily achieved in sequential depositions.

Aperture masks patterns can also be formed in one or more elongated webs of flexible film. Materials can be sequentially deposited through aperture mask patterns formed in the webs to define layers or elements of a TFT or circuit. A deposition substrate can also be formed from an elongated web, and the deposition substrate web can be fed through a series of deposition stations. Each deposition station can have its own elongated web formed with aperture mask patterns.

Preferably, the flexible mask is sufficiently flexible such that it can be wound to form a roll without damage. The flexible mask can also be stretchable (for example, stretchable in a cross-web direction, a down-web direction, or both) such that it can be stretched to achieve precise alignment. The flexible mask can be comprised of one or more of a wide variety of polymer such as, for example, polyimide, polyester, polystyrene, polymethyl methacrylate, polycarbonate, and the like. Preferably, the flexible mask comprises polyimide. The web of flexible film is typically at least about 3 cm in width, and less than about 200 microns in thickness (preferably, less than about 30 microns; more preferably, less than about 10 microns).

Laser ablation techniques can be used to define deposition aperture patterns in webs of flexible film. The aperture mask pattern is subject to a wide variety of shapes and sizes. Each aperture mask formed in a web of flexible material can define a number of patterns. The different patterns can define different layers of a TFT or circuit, or the different patterns can define different portions of the same TFT or circuit layer.

In other cases, the different patterns can be substantially the same. Each of the different patterns can then be used to create substantially similar deposition layers for different TFTs or circuits. For example, in an in-line web process, a web of deposition substrates can pass perpendicular to the aperture mask. After each deposition, the web of deposition substrates can move in-line for the next deposition. Thus, a first pattern can be used to deposit a layer on the web of deposition substrates, and then a second pattern can be used in a similar deposition process further down the web of deposition substrates. Each portion of the aperture mask containing a pattern can also be reused on a different portion of the deposition substrate or on one or more different deposition substrates.

In-line aperture mask deposition techniques can be carried out, for example, by traveling a web of polymeric film formed with aperture mask patterns past a deposition substrate. A first pattern in the web of polymeric film can be aligned with a deposition substrate, and a deposition process can be performed to deposit material on the deposition substrate according to the first pattern. Then, the web of polymeric film can be moved such that a second pattern aligns with the deposition substrate, and a second deposition process can be performed. The process can be repeated for any number of patterns formed in the web of polymeric film. The aperture mask pattern of polymeric film can be reused by repeating the above steps on a different deposition substrate or a different portion of the same substrate.

In-line aperture mask deposition techniques can also be carried out using a deposition substrate that comprises a web. That is, both the aperture mask and the deposition substrate can comprise webs. The webs can be made, for example, from polymeric material. Alternatively, a deposition substrate web can comprise a conveyance web carrying a series of discrete substrates. A first pattern in the aperture mask web can be aligned with the deposition substrate web for a first deposition process. Then, either or both the aperture mask web and the deposition substrate web can be moved such that a second pattern in the aperture mask web is aligned with the deposition substrate web and a second deposition process performed. If each of the aperture mask patterns in the aperture mask web are substantially similar, the technique can be used to deposit similar deposition layers in a number of sequential locations along the deposition substrate web.

Further details regarding aperture masks can be found in copending applications Ser. Nos. 10/076003, 10/076005, and 10/076174, all filed on Feb. 14, 2002, which are herein incorporated by reference.

Optional Layers

The present invention further provides a thin film transistor comprising a surface treatment layer disposed between the described organic semiconductor and the gate dielectric. The surface treatment layer can be selected from a nonfluorinated polymeric layer, a self-assembled monolayer, or a siloxane polymeric layer. The surface treatment layer provides OTFTs with one or more improvements over known devices, including improvements in properties such as threshold voltage, subthreshold slope, on/off ratio, and charge-carrier mobility. In addition, large improvements in at least one property, such as charge-carrier mobility, can be achieved with the surface treatment layer, while maintaining other OTFT properties within desirable ranges. The improvements in device performance provided by the present invention enable the production by simpler processing conditions of complex circuits having higher operating speeds than an OTFT made without the surface treatment layer. This surface treatment layer also enables the production of larger circuit elements having comparable performance to devices with very small features. Devices with larger feature sizes can be less expensive as they do not require expensive precision patterning methods.

The surface treatment layer can comprise a substantially nonfluorinated polymeric layer (“polymeric layer”) interposed between the gate dielectric and the semiconductor layer. As used herein, “substantially nonfluorinated” means less than about 5% (preferably, less than about 1%; more preferably, 0%) of the carbons in the polymeric layer have fluorine substituents. This polymeric layer can improve one or more properties such as threshold voltage, subthreshold slope, on/off ratio, and charge-carrier mobility.

Suitable materials for the polymeric layer include polymers derived from monomeric precursors, monomers, and oligomers comprising an aromatic-functional segment (for example, aromatic thermoset polymers such as polyarylenes); and polymers derived from a ring-opening polymerization (for example, straight-chain or branched C₁-C₁₈ alkyl-substituted norbornenes, trialkoxysilyl-substituted norbornenes, esters of 5-norbornene-2-carboxylic acid, esters of 2-phosphono-5-norbornene, 1,4-cyclooctadiene, and dicyclopentadiene).

The polymeric layer can also comprise a polymer having interpolymerized units according to the formula: 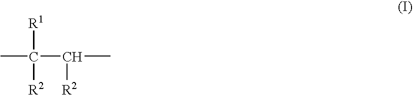
in an amount from about from about 50 to 100% of the interpolymerized units, and from 0 to about 50% of the interpolymerized units according to the formula: 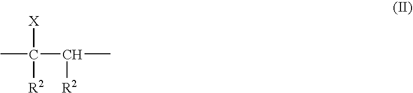
wherein each R¹ and R² comprises a group independently selected from hydrogen, C₁-C₂₀ aliphatics, chloro, bromo, carboxy, acyloxy, nitrile, amido, alkoxy, carboalkoxy, aryloxy, chlorinated aliphatics, brominated aliphatics, C₆-C₂₀ aryls, C₇-C₂₀ arylalkyls, hydroxy when R¹ and X are different, and combinations thereof which can contain one or more heteroatoms and one or more functional groups; and each X independently comprises a functional group capable of bonding to the gate dielectric (for example, —PO₃H₂, —OPO₃H₂, and trimethoxysilyl). In addition, any combination of at least two R¹, R², and/or X groups may together form a cyclic or polycyclic aliphatic, aromatic, or polycyclic aromatic group.

Specific examples of materials having interpolymerized units of Formula I, and optionally Formula II, include homopolymers such as polystyrene, poly(1-hexene), poly(methyl methacrylate), poly(acenaphthylene), poly(vinylnaphthalene), poly(butadiene), poly(vinyl acetate), and those derived from α-methylstyrene, 4-tert-butylstyrene, 2-methylstyrene, 3-methylstyrene, and 4-methylstyrene. In such homopolymer examples, the polymeric layer comprises 0% of the interpolymerized units according to Formula II.

The polymeric layer generally has a thickness of less than about 400 Angstroms (Å) (preferably, less than about 200 Å; more preferably, less than about 100 Å) and of at least about 5 Å (preferably, at least about 10 Å). It can be provided on the gate dielectric by vapor deposition.

TFTs made according to the present invention can also optionally include a self-assembled monolayer interposed between the gate dielectric and the semiconductor layer. As used herein, the term “self-assembled monolayer” or “SAM” refers to a mono-molecular layer on the order of about 5 Å to about 30 Å thick. The SAM is a product of a reaction between the gate dielectric and a precursor to the SAM. The SAM precursor typically comprises a composition having the formula:
X—Y-Zₙ
wherein

X is H or CH₃;

Y is a linear or branched C₅-C₅₀ alipahtic or cyclic aliphatic connecting group, or a linear or branched C₈-C₅₀ group comprising an aromatic group and a C₃-C₄₄ aliphatic or cyclic aliphatic connecting group;

Z is selected from —PO₃H₂, —OPO₃H₂, benzotriazoylyl (—C₆H₄N₃), carbonyloxybenzotriazole (—OC(=O)C₆H₄N₃), oxybenzotriazole (—O—C₆H₄N₃), aminobenzotriazole (—NH—C₆H₄N₃), —CONHOH, —COOH, —OH, —SH, —COSH, —COSeH, —C₅H₄N, —SeH, —SO₃H, isonitrile (—NC), chlorodimethylsilyl (—SiCl(CH₃)₂), dichloromethylsilyl (—SiCl₂CH₃), amino, and phosphinyl; and

n is 1, 2, or 3 provided that n is 1 when Z is —SiCl(CH₃)₂ or —SiCl₂CH₃.

Suitable SAM precursors include, for example, 1-phosphonooctane, 1-phosphonohexane, 1-phosphono-2-ethylhexane, 1-phosphono-2,4,4-trimethylpentane, and 1-phosphono-3,5,5-trimethylhexane, and 1-phosphono-3,7,11,15-tetramethylhexadecane.

The SAM precursor can be provided on the gate dielectric by known methods such as, for example, a coating process such as spray, spin, dip, gravure, microcontact printing, inkjet printing, stamping, transfer printing, or vapor deposition. The monolayer precursor is allowed to interact with the gate dielectric surface. The interaction or reaction may be instantaneous or may require time, in which case increasing the temperature can reduce the necessary time. When a solution of the SAM precursor is provided on the gate dielectric layer, the solvent is removed by a method compatible with the materials involved, for example by heating. Any excess SAM precursor is typically rinsed away before deposition of the organic semiconductor.

The addition of a SAM to a TFT can provide improvements in properties such as threshold voltage, subthreshold slope, on/off ratio, and charge-carrier mobility over devices that lack a SAM.

The surface treatment layer can also comprise a substantially siloxane polymeric layer (“siloxane polymeric layer”) having a thickness less than about 400 Å interposed between a gate dielectric and an organic semiconductor layer in an OTFT. The siloxane polymeric layer comprises a substantially nonfluorinated polymer having interpolymerized units according to the formula: 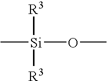
wherein each R³ comprises, independently, a group selected from hydrogen, C₁-C₂₀ aliphatic, C₄-C₂₀ alicyclic, arylalkyl, or aryl, and a combination thereof which may contain one or more heteroatom(s) and/or one or more functional group(s). As used herein, “heteroatom” means a non-carbon atom such as O, P, S, N and Si, and “substantially nonfluorinated” means that less than about 5% (preferably, less than about 1%; more preferably, 0%) of the carbons in the polymeric layer have fluorine substituents.

The siloxane polymeric layer has a maximum thickness less than about 400 Angstroms (Å), more preferably less than about 200 Å, most preferably less than about 100 Å. The siloxane polymeric layer generally has a thickness of at least about 5 Å, more preferably at least about 10 Å. The thickness can be determined through known methods, e.g., ellipsometry.

Particular selections for R³ groups include, for example, methyl, phenyl, 2-phenylethyl, C₂-C₁₈ aliphatic groups, and functional group-containing moieties including, but not limited to, hydroxyl, vinyl, 5-hexenyl, hydrogen, chloro, 3-(meth)acryloxypropyl, 3-mercaptopropyl, 3-glycidoxypropyl, 2-(3,4-epoxycyclohexyl)ethyl, 3-aminopropyl, 3-acetoxypropyl, 3-chloropropyl, 3-carboxypropyl, 3-cyanopropyl, chlorophenyl, C₁-C₆2-(dialkylphosphono)ethyl.

Examples of useful polymeric materials for the siloxane polymeric layer include poly(dimethylsiloxane), poly(dimethylsiloxane-co-diphenylsiloxane), poly(methylphenylsiloxane-co-diphenylsiloxane), and poly(dimethylsiloxane-co-methylphenylsiloxane).

Siloxane polymers useful in the practice of this invention can be prepared by any of a number of methods familiar to those skilled in the art, including, for example, anionic, condensation, or ring-opening polymerization. Siloxane polymers useful for this invention may also be prepared with the introduction of functional end-groups or functional pendant groups. This can be accomplished through the use of functional monomers, functional initiators, or functional chain terminators, for example, the termination of an anionically polymerized polydiorganosiloxane with a chlorotrialkoxysilane. They can also be prepared by modification of existing siloxane polymers, for example, the reaction of an olefinically functional polydiorganosiloxane with a silicon hydride such as, for example, trichlorosilane.

While this invention emphasizes the use of linear polydiorganosiloxanes in which each unit in the siloxane polymer is derived from a difunctional precursor, it is considered within the scope of this invention to employ polyorganosiloxanes that incorporate small amounts of siloxane units derived from trifunctional or tetrafunctional precursors. The number of trifunctionally—and tetrafunctionally-derived siloxane units should not exceed about 10 percent, preferably about 5 percent or less, of the total average number of siloxane units in the polymer. ps Integrated Circuits

A plurality of TFTs can be interconnected to form an integrated circuit (IC). Integrated circuits include but are not limited to, for example, ring oscillators, radio-frequency identification (RFID) circuitry, logic elements, amplifiers, and clocks. Therefore, sealed TFTs made according to the methods of present invention can be interconnected to other TFTs by means known in the art to form ICs. Sealed TFTs can also be used in various electronic articles such as, for example, RFID tags, backplanes for displays (for use in, for example, personal computers, cell phones, or handheld devices), smart cards, memory devices, and the like. Sealed TFTs made according to the methods of the invention are particularly well-suited for use as backplanes for displays because the sealing layer provides a barrier to the liquids often used in the displays.

Typically, when TFT ICs are made using aperture masking techniques, long electrically conducting lines are made by connecting shorter line segments on two or more conducting TFT layers (for example, the gate electrode layer and the source and drain electrode layer) in order to overcome limitations associated with stenciled patterns. In many applications, particularly display backplanes (for example, for liquid crystal or organic light emitting diode (OLED) active matrix displays), it is desirable to cover all of the circuitry except for the pixel electrode with insulating material. The insulating material minimizes the visibility of the TFT and the conducting lines by electrically insulating them from the display medium (for example, the liquid crystal or OLED). However, depositing insulating material, which covers everything except the pixel electrodes using aperture masking techniques is not possible because the pixel electrodes are disconnected isolated from each other. Surprisingly, it is possible to completely insulate the conducting lines and TFTs from the display medium with only the gate dielectric layer and the TFT sealing layer using aperture masking techniques. This invention can be applied, for example, by using the sealing layer in concert with a second insulating layer (for example, the gate insulator layer) to fully cover selected portions of an integrated circuit with insulating material.

Therefore, unsealed TFTs that are part of an IC can be sealed using the methods of the invention. Further, the same teachings described above can be used for sealing the elements of an IC (for example, the leads or interconnects).

### EXAMPLES

Objects and advantages of this invention are further illustrated by the following examples, but the particular materials and amounts thereof recited in these examples, as well as other conditions and details, should not be construed to unduly limit this invention.

Fabrication of Sealed Organic Thin Film Transistors (OTFTs)

Four 2 inch by 2 inch Kapton™ polyimide aperture masks were made essentially as described in copending application Ser. No. 10/076003, filed on Feb. 14, 2002. The aperture masks were designed to provide a TFT having channel lengths of 20 microns and line widths of 30 microns.

Two inch square float glass slides were purchased from Precision Glass and Optics (Santa Ana, Calif.). A glass slide 22 was placed in concentrated hydrochloric acid for about one minute. The slide was then removed from the acid, rinsed with deionized water, and blown dry with nitrogen. The dry slide was then wiped with isopropanol using a TX1009 TexWipe™ (ITW Texwipe, Upper Saddle River, N.J.). The slide was then placed upon a 100° C. hot plate for two minutes. The first aperture mask was then placed on the slide and held in place using a small hand jig. The slide was loaded into a first vacuum chamber for deposition.

A titanium/gold (Ti/Au) gate layer 24 was deposited through the aperture mask onto the glass slide 22 by electron beam evaporating Ti (at a rate of 3 Å per second to reach a thickness of 20 Å as measured by a quartz crystal microbalance) in a vacuum chamber at a pressure of 2×10⁻⁶ torr and then thermally evaporating Au in the same vacuum chamber and the same pressure (at a rate of 5 Å per second to reach a thickness of 600 Å). The resulting sample was removed from the vacuum chamber. The first aperture mask was removed from the sample. The second aperture mask was then aligned on the sample using a microscope and held in place with the jig. The sample was loaded back into the first vacuum chamber.

An aluminum oxide dielectric layer 26 was deposited through the second aperture mask onto the gate layer 24 by electron beam evaporation at a rate of 3 Å per second to reach a thickness of 2000 Å. During the deposition, a small water reservoir was opened to the vacuum chamber to allow the pressure to remain at about 5×10⁻⁵ torr. The sample was again removed from the vacuum chamber, and the second aperture mask was removed. A polymeric surface-modifying layer 27 was provided by applying a few ml a 0.1% wt solution of poly(α-methylstyrene) (average molecular weight, M_{w,} 680,000 g/mol) in toluene onto the dielectric layer 26 and then spinning the sample at 500 rpm for 20 seconds and 1500 rpm for 40 seconds. The treated sample was then baked in an oven at 120° C. for 30 minutes. The third aperture mask was then aligned on the sample using the microscope and held in place with the jig. The sample was loaded back into the first vacuum chamber for semiconductor deposition.

Pentacene (Aldrich Chemical Co, Milwaukee, Wis.) was purified in a 3-zone furnace (Thermolyne 79500 tube furnace, Barnstead Thermolyne, Dubuque, Iowa) at reduced pressure under a constant flow of 96% nitrogen and 4% hydrogen gas at a maximum temperature of 300° C. The purified pentacene was deposited through the third aperture mask by sublimation under vacuum (approximately 10⁻⁶ torr) onto the polymeric surface-modifying layer 27 at a rate of 0.5 Å per second to reach a thickness of 300 Å as measured by atomic force microscope step height images to provide a pentacene semiconductor layer 28. The sample was removed from the vacuum chamber. The third aperture mask removed from the sample. The fourth aperture mask was then aligned on the sample using the microscope and held in place with the jig. The sample was loaded back into a second vacuum chamber.

The gold (Au) source 30 and drain 32 layer were deposited by thermal evaporation (in a vacuum of 2×10⁻⁶ torr) through the fourth aperture mask at a rate of 5 Å per second to provide layers having a thickness of 600 Å. The sample was removed from the vacuum chamber. The fourth aperture mask was removed from the sample. The second aperture mask then realigned on the sample using the microscope and held in place with the jig. The sample was loaded back into the first vacuum chamber.

Aluminum oxide was deposited through the second aperture mask by electron beam evaporation at a pressure of 2×10⁻⁵ torr at a rate of 3 Å per second to provide a sealant layer 34 with a thickness of 2000 Å. The sample was removed from the first vacuum chamber, and the second mask was removed.

Method for Performance Testing of Sealed OTFTs

Transistor performance was tested at room temperature in air using techniques in the art, for example as shown in S. M. Sze, Physics of Semiconductor Devices, page 442, John Wiley & Sons, New York, 1981. A Semiconductor Parameter Analyzer (Model 4145A from Hewlett-Packard, Palo Alto, Calif.) was used to obtain the results. The square root of the drain current (Id) was plotted as a function of gate-source bias (Vg) from +10V to −40V for a constant source-drain bias of −40V. The saturation field effect mobility was calculated from the straight-line portion of the curve using the specific capacitance of the gate dielectric, the channel width and the channel length. The x-axis extrapolation of this straight-line fit was taken as the threshold voltage (Vth). In addition, plotting Id as a function of Vg yielded a curve where a straight line fit was drawn along a portion of the curve containing Vt. The inverse of the slope of this line was the subthreshold slope (S). The “on-off” ratio was taken as the difference between the minimum and maximum drain current values of the Id-Vg curve.

### Example 1

Sealed transistor OTFT 1 was fabricated and performance tested according to the methods described above. Table I lists performance characteristics of OTFT 1 over twenty-two days.

TABLE 1

| | Mobility | | Slope | |
|---|---|---|---|---|
| Time | (cm²/V · sec) | Vth | (V/decade) | On/Off |
| Day 0 | 2.194 | −13.34 | 1.851 | 3e⁺⁵ |
| Day 10 | 2.405 | −5.864 | 1.366 | 1.3e⁺⁷ |
| Day 22 | 2.452 | −7.219 | 1.353 | 3e⁺⁷ |

### Examples 2-3

Sealed transistors OTFT 2 and OTFT 3 were fabricated according to the method described above, exposed to various environments, and then performance tested. The performance tests were performed as described above with the following change: the square root of the drain current (Id) was plotted as a function of gate-source bias (Vg) from +10V to −30V for a constant source-drain bias (Vd) of −30V. The test results are listed in Table 2 .

OTFT 2 was then washed with acetone for about 1 minute. OTFT 2 was then blown dry with nitrogen and performance tested again. The results are listed in Table 2. OTFT 3 was exposed to steam for about 1 minute, was blown dry with nitrogen, and was then performance tested again. The results are also shown in Table 2.

TABLE 2

| | Mobility | | Slope | |
|---|---|---|---|---|
| | (cm²/V · sec) | Vth | (V/decade) | On/Off |
| OTFT 2 | 1.035 | −8.831 | 1.852 | 2.3e⁺⁵ |
| OTFT 2 | 0.776 | −7.852 | 2.553 | 6.7e⁺⁵ |
| acetone treatment | | | | |
| OTFT 3 | 1.011 | −9.79 | 1.457 | 1.9e⁺⁶ |
| OTFT 3 | 1.027 | −10.39 | 1.103 | 3.1e⁺⁶ |
| steam treatment | | | | |

Various modifications and alterations to this invention will become apparent to those skilled in the art without departing from the scope and spirit of this invention. It should be understood that this invention is not intended to be unduly limited by the illustrative embodiments and examples set forth herein and that such examples and embodiments are presented by way of example only with the scope of the invention intended to be limited only by the claims set forth herein as follows.

We claim:

1. A method for sealing a thin film transistor comprising the steps of:
(a) providing a thin film transistor comprising a gate electrode, a gate dielectric, a source and a drain electrode, and a semiconductor layer; and
(b) vapor depositing a sealing material on at least a portion of said semiconductor layer through a pattern of an aperture mask.

2. The method of claim 1 wherein said sealing material forms a pre selected pattern on at least a portion of said semiconductor layer.

3. The method of claim 1 wherein said sealing material has a resistivity of at least 10× that of said semiconductor layer.

4. The method of claim 1 wherein said sealing material has a resistivity of at least 100× that of said semiconductor layer.

5. The method of claim 1 wherein said sealing material has a resistivity of at least 1×10⁶ ohm-cm.

6. The method of claim 1 wherein said sealing material is a metal oxide, metal nitride, silicon oxide, silicon nitride, or a polymer.

7. The method of claim 6 wherein said polymer is parylene.

8. The method of claim 1 wherein said sealing material is transparent.

9. The method of claim 1 wherein said semiconductor layer is an organic semiconductor.

10. The method of claim 9 wherein said organic semiconductor comprises pentacene or a substituted pentacene.

11. The method of claim 1 wherein said aperture mask is a polymeric aperture mask.

12. The method of claim 9 wherein said thin film transistor further comprises a surface treatment layer interposed between said dielectric layer and said semiconductor layer.

13. The method of claim 1 further comprising the step of vapor depositing a metal layer on said sealing material through said pattern of said aperture mask.

14. The method of claim 1 further comprising the step of interconnecting said thin film transistor to at least one other thin film transistor to form an integrated circuit.

15. The method of claim 1 wherein said thin film transistor is part of an integrated circuit.

16. The method of claim 15 wherein said sealing material covers at least a portion of said integrated circuit.

17. The method of claim 16 wherein said sealing material covers at least a portion of conducting lines of said integrated circuit.

18. A method of making a thin film transistor comprising the steps of:
(a) providing a substrate;
(b) depositing a gate electrode material on said substrate through a pattern of an aperture mask;
(c) depositing a gate dielectric on said gate electrode material through a pattern of an aperture mask;
(d) depositing a semiconductor layer adjacent to said gate dielectric through a pattern of an aperture mask;
(e) depositing a source electrode and a drain electrode contiguous to said semiconductor layer through a pattern of an aperture mask; and
(f) vapor depositing a sealing material on at least a portion of said semiconductor layer through a pattern of an aperture mask.

19. The method of claim 18 wherein at least one of said depositing steps (b) to (e) are vapor depositing steps under vacuum.

20. The method of claim 19 wherein all of said depositing steps (b) to (e) are vapor depositing steps under vacuum.

21. The method of claim 20 wherein the method is carried out in its entirety without breaking vacuum.

22. The method of claim 18 wherein the steps are performed in the order listed.

23. The method of claim 18 wherein said sealing material has a resistivity of at least 10× that of said semiconductor layer.

24. The method of claim 23 wherein said sealing material is transparent.

25. The method of claim 18 wherein said semiconductor layer is an organic semiconductor.

26. The method of claim 25 wherein said organic semiconductor layer comprises pentacene or a substituted pentacene.

27. The method of claim 18 wherein said gate electrode material, gate dielectric, semiconductor layer, source and drain electrodes, and sealing material are deposited through a single aperture mask formed with a pattern of deposition apertures.

28. The method of claim 18 wherein said gate electrode material, gate dielectric, semiconductor layer, source and drain electrodes, and sealing material are each deposited through a separate aperture mask of a mask set.

29. The method of claim 18 further comprising the step of depositing a surface treatment layer between said dielectric layer and said semiconductor layer.

30. A transistor comprising a substrate, a gate electrode, a gate dielectric, a source and drain electrode, a semiconductor layer, and a vapor deposited sealing layer on at least a portion of said semiconductor layer.
